(19) United States
(12) Patent Application Publication
(10) Pub. No.: US 2026/0282796 A1
(43) Pub. Date: Sep. 17, 2026

(54) DRY ETCHING APPARATUS

(71) Applicant: TDK Corporation, Tokyo (JP)

(72) Inventors: Kazushi NISHIYAMA, Hong Kong (CN); Takashi MATSUHASHI, Hong Kong (CN); Tetsuya MINO, Hong Kong (CN); Cheng Bu HENG, Hong Kong (CN)

(73) Assignee: TDK Corporation, Tokyo (JP)

(21) Appl. No.: 19/565,722

(22) Filed: Mar. 13, 2026

(30) Foreign Application Priority Data
Mar. 14, 2025 (JP) 2025-041179

(51) Int. Cl. H10P 72/00

(52) U.S. Cl. CPC H10P 72/0421

(57) ABSTRACT

The dry etching apparatus includes a rotatable sample stage on which a sample is mounted, an etching source for emitting an etching medium to the sample, and a shielding part provided at a position remote from the sample stage to block part of the emitted etching medium from reaching the sample.

### CROSS REFERENCE TO RELATED APPLICATION

This application claims the benefit of Japanese Priority Patent Application No. 2025-041179 filed on Mar. 14, 2025, the entire contents of which are incorporated herein by reference.

### FIELD

The present disclosure relates to a dry etching apparatus.

### BACKGROUND

A dry etching apparatus for etching a sample by irradiation with an ion beam is known (for example, see Patent Publication JP-A-2013-101851 and Patent Publication JP-A-H09-33410).

A dry etching apparatus is used, for example, for uniformly etching the surface of a thin film formed on a wafer. Here, for example, a thin film formed on a wafer by a film forming device such as a sputtering device tends to have a thickness distribution in a concentric circle because of the nature of the film forming method. Specifically, the thin film formed on the wafer may gradually decrease in thickness from the peripheral portion to the center, or conversely, gradually increase in thickness. In such a case, it may be necessary to eliminate the thickness distribution of the thin film and obtain a uniform thickness in the plane. On the contrary, it may be desired to intentionally generate a thickness distribution in a concentric circle for a thin film having a uniform thickness in the plane. It is considered that these requests can be met by etching a sample while changing the etching rate concentrically. Conventional dry etching apparatuses can uniformly etch the surface of a workpiece but are difficult to etch the surface of the workpiece while changing the etching rate concentrically.

One aspect of the present disclosure has been devised to solve such a problem and provide a dry etching apparatus capable of adjusting the etching rate concentrically.

### SUMMARY

A dry etching apparatus of the present disclosure includes a rotatable sample stage on which a sample is mounted, an etching source for emitting an etching medium to the sample, and a shielding part provided at a position remote from the sample stage to block part of the emitted etching medium from reaching the sample.

The present disclosure can provide a dry etching apparatus capable of adjusting the etching rate concentrically.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a schematic diagram of a dry etching apparatus;

FIG. 2 is a plan view showing an example of the shape of a shielding part in top view;

FIG. 3 is a plan view showing an example of the shape of the shielding part in top view;

FIG. 4 is a plan view showing an example of an etching rate that increases from the peripheral portion to the center of a sample;

FIG. 5 is a plan view showing an example of an etching rate that increases from the center to the peripheral portion of the sample;

FIG. 6 is a schematic diagram when a thin film that has increased in thickness from the peripheral portion to the center of the sample is caused to have a uniform thickness in the plane;

FIG. 7 is a schematic diagram when a thin film that has increased in thickness from the center to the peripheral portion of the sample is caused to have a uniform thickness in the plane;

FIG. 8 is a schematic diagram when a thickness distribution is generated in a concentric circle, in which the thickness increases from the center to the peripheral portion of the sample, for a thin film having a uniform thickness in the plane;

FIG. 9 is a schematic diagram when a thickness distribution is generated in a concentric circle, in which the thickness increases from the peripheral portion to the center of the sample, for a thin film having a uniform thickness in the plane;

FIG. 10 is an enlarged view of a portion A indicating a portion of the sample in FIG. 1;

FIG. 11 is a schematic diagram when the surface of the sample is polished by chemical-mechanical polishing;

FIG. 12 is a schematic diagram when the surface of the sample is trimmed with a trimmer;

FIG. 13 is a schematic diagram when the surface of the sample is etched by the dry etching apparatus of the example embodiment;

FIG. 14 is a graph showing an etching rate [nm/sec]; and

FIG. 15 is a graph showing the thicknesses [nm] of the thin film before etching, after short-time etching, and after long-time etching.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

An example embodiment of the present disclosure will be described below with reference to the accompanying drawings. In the drawings, elements assigned with the same reference numerals have the same or similar configuration. The disclosure according to the claims is not limited to the example embodiment described below. Furthermore, not all the configurations described in the example embodiment are essential as means for solving the problem.

As shown in FIG. 1, a dry etching apparatus 10 of the example embodiment includes: a sample stage 11, an etching source 12, and a shielding part 13. An etching method used in the dry etching apparatus 10 may be any one of sputter etching, reactive ion etching (RIE), and gas etching, but from the viewpoint of easy adjustment of the etching rate, highly anisotropic sputter etching or reactive ion etching is preferable. From the viewpoint of easy adjustment of the irradiation angle of an etching medium 20 on a sample 30, ion beam etching (IBE) of sputter etching is particularly preferable as the etching method. Ion beam etching includes ion milling.

The sample stage 11 is a stage on which the sample 30 is mounted when the dry etching apparatus 10 is used. The sample stage 11 can rotate on its axis. For example, a rotation is made by a motor, and the rotation speed can be adjusted as appropriate. The sample stage 11 may be capable of changing the inclination of the sample 30 so as to adjust the irradiation angle of the etching medium 20 on the sample 30.

The etching source 12 irradiates the sample 30 with the etching medium 20. When the etching method is ion beam etching, the etching source 12 is an ion gun, and the etching medium 20 is an ion beam. Ions serving as the ion beam can be, for example, argon ions, helium ions, xenon ions, or krypton ions. One or more etching sources 12 may be provided. The position and/or orientation of the etching source 12 may be changeable so as to adjust the irradiation angle of the etching medium 20 on the sample 30.

When the shielding part 13 does not block the etching source 12, for example, the etching source 12 emits the etching medium 20 to the overall surface of the sample 30 mounted on the sample stage 11. That is, when the shielding part 13 does not block the etching source 12, the irradiation range of the etching medium 20 may include the overall surface of the sample 30 mounted on the sample stage 11.

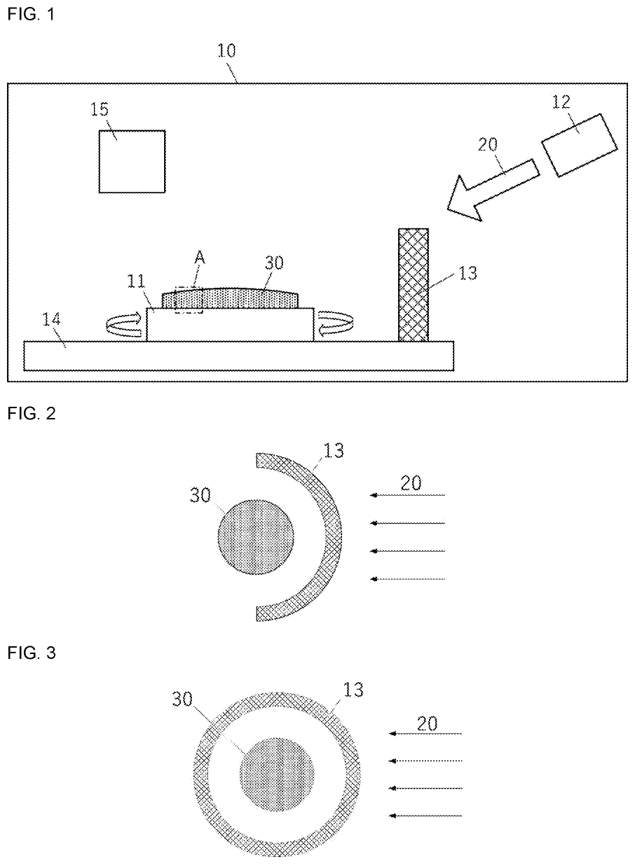

The shielding part 13 is provided at a position remote from the sample stage 11 so as to block part of the emitted etching medium 20 from reaching the sample 30. The material of the shielding part 13 is not particularly limited if the material can block the etching medium 20, and may be, for example, metal, ceramic, or resin. In the example embodiment, although the shielding part 13 is assumed to be an arc-shaped wall standing on a pedestal 14, the shape is not particularly limited. The shielding part 13 may have any shape if the shielding part 13 can partially block the etching medium. For example, the height of the shielding part 13 standing from the pedestal 14 and the contour of the shielding part 13 observed from above can be changed in various ways. The shape of the shielding part 13 in top view is identical to the shape of the shielding part 13 viewed in parallel with the rotation axis of the sample 30. For example, the shielding part 13 may have an arc shape as shown in FIG. 2 or an annular shape surrounding the sample 30 as shown in FIG. 3. The shielding part 13 may be composed of a single structure or a combination of multiple structures.

As shown in FIG. 1, the etching source 12 emits the etching medium 20, for example, diagonally with respect to the rotation axis of the sample stage 11. In this case, the shielding part 13 is located at an appropriate height in the lateral direction (a direction perpendicular to the rotation axis) of the sample stage 11, thereby partially blocking the etching medium 20. Alternatively, the etching source 12 may emit the etching medium 20 in parallel with the rotation axis of the sample stage 11. In this case, the shielding part 13 partially covers, for example, the sample stage 11, thereby partially blocking the etching medium 20.

As shown in FIG. 1, the sample stage 11 and the shielding part 13 that are separated from each other may be disposed on the pedestal 14. In this case, the pedestal 14 does not rotate even when the sample stage 11 rotates on its axis. In other words, the shielding part 13 separated from the sample stage 11 on the pedestal 14 does not make a rotation following the sample stage 11 when the sample stage 11 rotates on its axis. In addition, the position and/or orientation of the pedestal 14 may be changeable so as to adjust the irradiation angle of the etching medium 20 on the sample 30.

As described above, the dry etching apparatus 10 of the example embodiment includes: the rotatable sample stage 11, and the shielding part 13 provided at a position remote from the sample stage 11 to block part of the emitted etching medium 20 from reaching the sample 30. The shielding part 13 forms an etching range and a non-etching range on the surface of the sample 30. Furthermore, in this state, the sample 30 rotating with the rotation of the sample stage 11 forms, for example, the range of continuous etching and the range of intermittent etching, thereby generating an etching-rate distribution. The etching-rate distribution is generated by the rotation of the sample 30 and thus is formed into a concentric circle. The etching-rate distribution like a concentric circle can be adjusted by adjusting the range of a region in which the etching medium 20 is blocked by the shielding part 13 (blocking region) on the sample 30. The range of the blocking region can be adjusted by adjusting the shape of the shielding part 13, the position of the shielding part 13, and the irradiation angle or the like. The irradiation angle can be adjusted by adjusting the relative position and angle of the etching source 12 with respect to the sample stage 11. Thus, the dry etching apparatus 10 of the example embodiment can adjust the etching rate concentrically.

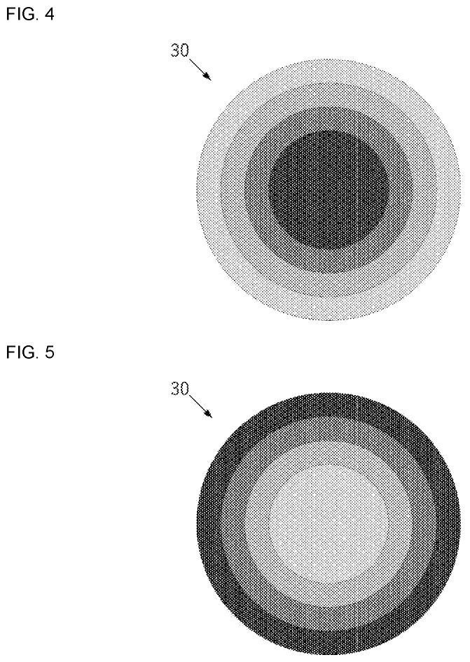

Furthermore, for example, the shape of the shielding part 13, the position of the shielding part 13, and the irradiation angle or the like can be changed stepwise or gently during etching, so that the etching-rate distribution can be changed stepwise or gently. FIG. 4 shows an example of an etching rate that increases from the peripheral portion to the center of the sample 30. FIG. 5 shows an example of an etching rate that increases from the center to the peripheral portion of the sample 30. In FIGS. 4 and 5, the depth of color indicates the magnitude of the etching rate.

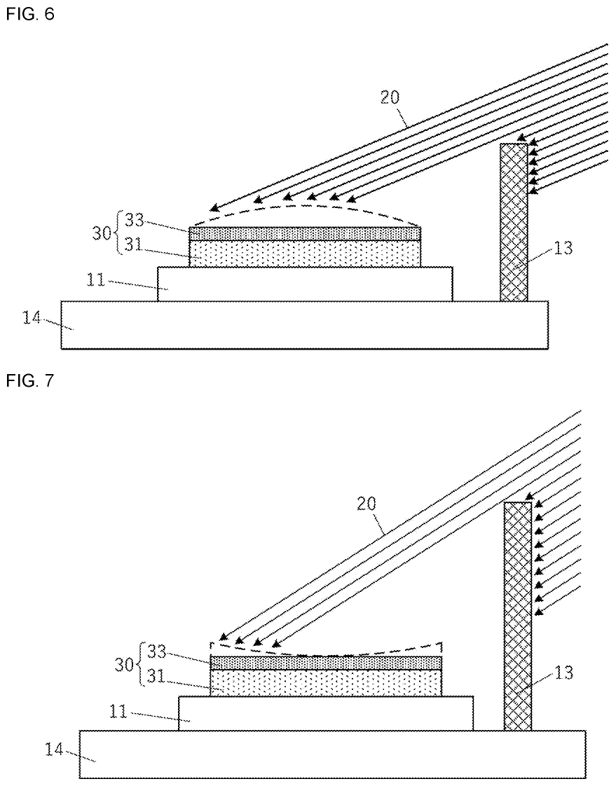

As described above, by concentrically adjusting the etching rate, for example, the thickness of a concentrically distributed thin film 33 can be made uniform in the plane. FIG. 6 is a schematic diagram showing that the thin film 33 increasing in thickness from the peripheral portion to the central portion is caused to have a uniform thickness in the plane by using the dry etching apparatus 10 in which the range of the blocking region is adjusted to increase the etching rate from the peripheral portion to the central portion. FIG. 7 is a schematic diagram showing that the thin film 33 increasing in thickness from the central portion to the peripheral portion is caused to have a uniform thickness in the plane by using the dry etching apparatus 10 in which the range of the blocking region is adjusted to increase the etching rate from the central portion to the peripheral portion. The broken line in the drawing indicates the surface of the thin film 33 before etching. In the example shown in FIG. 6 and the example shown in FIG. 7, the ranges of the blocking region are different because the distance between the shielding part 13 and the sample 30, the height of the shielding part 13, and the irradiation angle are adjusted as appropriate. Consequently, the etching-rate distributions are different from each other.

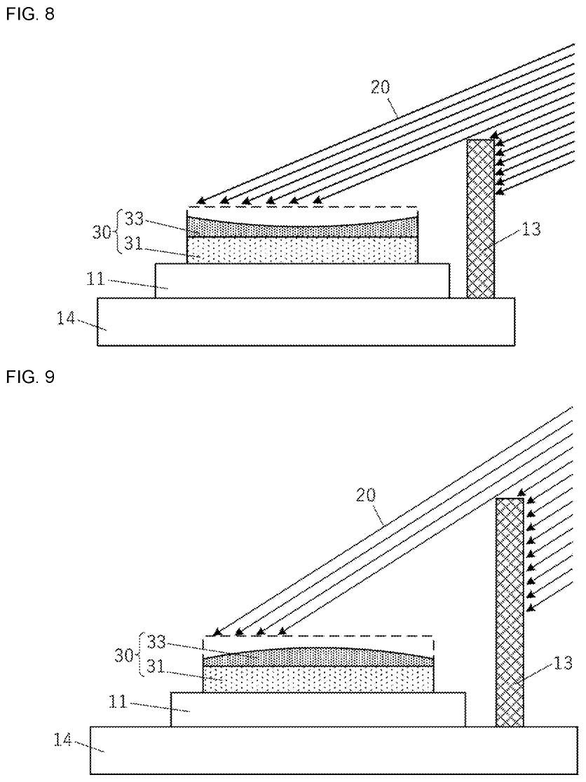

Moreover, by concentrically adjusting the etching rate, a thickness distribution can be concentrically generated with respect to the thin film 33 having a uniform thickness in the plane. FIG. 8 is a schematic diagram showing that by using the dry etching apparatus 10 in which the range of the blocking region is adjusted to increase the etching rate from the peripheral portion to the central portion, a thickness distribution increasing in thickness from the central portion to the peripheral portion is concentrically generated for the thin film 33 having a uniform thickness in the plane. FIG. 9 is a schematic diagram showing that by using the dry etching apparatus 10 in which the range of the blocking region is adjusted to increase the etching rate from the central portion to the peripheral portion, a thickness distribution increasing in thickness from the peripheral portion to the central portion is concentrically generated for the thin film 33 having a uniform thickness in the plane. Also in the example shown in FIG. 8 and the example shown in FIG. 9, the ranges of the blocking region are different because the distance between the shielding part 13 and the sample 30, the height of the shielding part 13, and the irradiation angle are adjusted as appropriate. Consequently, the etching-rate distributions are different from each other.

In the dry etching apparatus 10 of the example embodiment, when the thin film 33 formed on a lower layer structure 32 such as an electrode is etched, the thin film 33 can be easily etched without considerably changing the thickness of the thin film 33 at a portion overlapping the lower layer structure 32 and the thickness of the thin film 33 at a portion not overlapping the lower layer structure 32.

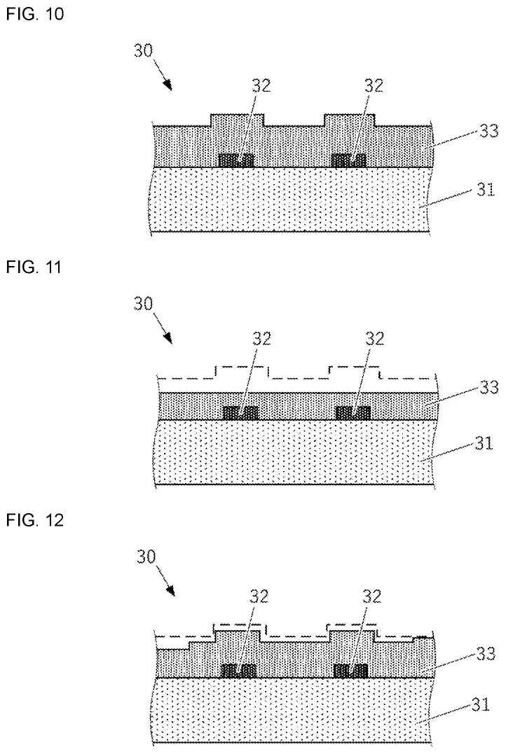

FIG. 10 is an enlarged view of a portion A in FIG. 1, showing a part of the sample 30. When the surface of the thin film 33 formed on the lower layer structure 32 is polished by chemical mechanical polishing (CMP) as a comparative example, the surface of the thin film 33 is smoothed as shown in FIG. 11. However, in this case, the thickness of the thin film 33 varies greatly in the portion overlapping the lower layer structure 32 and the portion not overlapping the lower layer structure 32. In FIGS. 11 to 13, the broken line indicates the surface of the thin film 33 before etching.

As another comparative example, an example using a trimmer will be described below. The trimmer is a device for trimming a material by irradiation of a gas cluster while scanning on the sample 30. When the surface of the thin film 33 formed on the lower layer structure 32 is trimmed with a trimmer, even if the thickness of the thin film 33 is to be made uniform in consideration of the presence of the lower layer structure 32, a region overlapping the irradiation range of the gas cluster and a region not overlapping the irradiation range of the gas cluster may be formed by scanning, or irradiation ranges with different cutting amounts may be adjacent to each other, so that a step is formed as shown in FIG. 12.

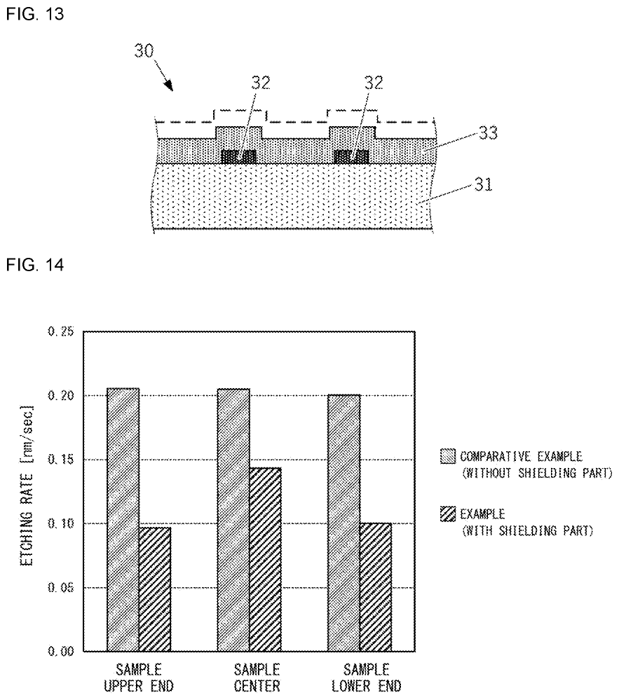

In contrast, when the surface of the thin film 33 formed on the lower layer structure 32 is etched by the dry etching apparatus 10 of the example embodiment, as shown in FIG. 13, the difference in the thickness of the thin film 33 between the portion overlapping the lower layer structure 32 and the portion not overlapping the lower layer structure 32 is less likely to occur due to the dry etching characteristics. Since such an effect is obtained, the dry etching apparatus 10 of the example embodiment is particularly useful, for example, when the thin film 33 is etched to have a uniform thickness at the portion overlapping the lower layer structure 32 and the portion not overlapping the lower layer structure 32.

As described above, the range of the region (blocking region) in which the etching medium 20 is blocked by the shielding part 13 on the sample 30 can be adjusted by the position of the shielding part 13, the shape of the shielding part 13, the irradiation angle of the etching medium 20 on the sample 30, and the like.

The position of the shielding part 13 is, for example, the distance from the sample 30 to the shielding part 13. If other conditions are the same, the range of the blocking region tends to be larger as the shielding part 13 is closer to the sample 30, and the range of the blocking region tends to be smaller as the shielding part 13 is farther from the sample 30.

As described above, the shape of the shielding part 13 includes the height of the shielding part 13, and the shape of the shielding part 13 in top view. If other conditions are the same, the range of the blocking region tends to be larger as the shielding part 13 increases in height, and the range of the blocking region tends to be smaller as the shielding part 13 decreases in height. Regarding the shape of the shielding part 13 in top view, for example, when the shielding part 13 is arc-shaped in top view and if other conditions are the same, the range of the blocking region tends to be larger as the central angle of the arc increases, and the range of the blocking region tends to be smaller as the central angle of the arc decreases.

The irradiation angle of the etching medium 20 on the sample 30 is, in other words, the angle of irradiation with the etching medium 20 with respect to the in-plane direction of the sample 30. If other conditions are the same, the range of the blocking region tends to be larger as the irradiation angle decreases, and the range of the blocking region tends to be smaller as the irradiation angle increases. The irradiation angle of the etching medium 20 on the sample 30 can be adjusted by changing the relative position and angle of the etching source 12 with respect to the sample stage 11.

At least one of the installation or non-installation of the shielding part 13, the position of the shielding part 13, the shape of the shielding part 13, and the irradiation angle of the etching medium 20 on the sample 30 may be changeable. Furthermore, it is preferable that at least one of the installation or non-installation of the shielding part 13, the position of the shielding part 13, the shape of the shielding part 13, and the irradiation angle of the etching medium 20 on the sample 30 is changeable. It is preferable that the installation or non-installation of the shielding part 13, the position of the shielding part 13, the shape of the shielding part 13, and the angle of irradiation with the etching medium 20 on the sample 30 are all changeable. In the dry etching apparatus 10 of the example embodiment, the shielding part 13 is separated from the sample stage 11, and thus it is easy to change the setting or non-setting of the shielding part 13, the position of the shielding part 13, and the shape of the shielding part 13.

The changeable installation or non-installation of the shielding part 13 means that the shielding part 13 can be removed from the dry etching apparatus 10 or the shielding part 13 can be moved to a position where irradiation with the etching medium 20 is not affected. The position where irradiation with the etching medium 20 is not affected may be, for example, a position on the opposite side of the sample stage 11 from the etching source 12 or a position under the pedestal 14. Since the installation or non-installation of the shielding part 13 is changeable, the dry etching apparatus 10 of the example embodiment can be used even in an ordinary application such as uniform etching over the surface of the sample 30.

The shielding part 13 may be fixed integrally with the dry etching apparatus 10. In this case, the manufacturing cost of the apparatus may be suppressed by simplification of the apparatus configuration.

The dry etching apparatus 10 may include a control unit 15 that controls at least one of the etching source 12, the sample stage 11, and the shielding part 13 to adjust a region where the etching medium 20 is blocked by the shielding part 13. In this case, the control unit 15 may change the irradiation angle of the etching medium 20 on the sample 30 by controlling the etching source 12 and/or the sample stage 11. Furthermore, the control unit 15 may also change at least one of the installation or non-installation of the shielding part 13, the position of the shielding part 13, and the shape of the shielding part 13 by controlling the shielding part 13.

The control unit 15 can change the position of the shielding part 13 by, for example, moving the shielding part 13 to a position under the pedestal 14 when the shielding part 13 is not necessary, and moving the shielding part 13 to a position where the shielding part 13 can block the etching medium 20 when the shielding part 13 is necessary.

The control unit 15 can change the shape of the shielding part 13 by, for example, enlarging or reducing the shielding part 13 in the circumferential direction and/or the height direction of the sample 30. Also, for example, if the shielding part 13 includes a plurality of plates that are bent into thin fan-shaped strips combined like bellows, the control unit 15 can change the shape of the shielding part 13 by folding the shielding part 13 shaped like bellows or moving only some of the plates.

The control unit 15 may change the range of the blocking region and the etching-rate distribution by changing the shape of the shielding part 13, the position of the shielding part 13, and the irradiation angle or the like stepwise during etching.

The control unit 15 may adjust the range of the blocking region by controlling at least one of the etching source 12, the sample stage 11, and the shielding part 13 on the basis of the etching target. The “etching target” is the target of the degree of etching on each portion of the sample 30.

The etching target is set by the control unit 15 on the basis of, for example, the state of the sample 30 before etching and the state of the sample 30 after target etching is performed.

The installation or non-installation of the shielding part 13, the position of the shielding part 13, the shape of the shielding part 13, and the irradiation angle of the etching medium 20 on the sample 30 may be changed by manual control by a user.

### EXAMPLES

The present disclosure will be described in further detail with reference to the following examples, which should not be construed as limiting the scope of the present disclosure.

The sample 30, on which the thin film 33 increasing in thickness from the peripheral portion to the central portion was formed, was prepared on a 6-inch substrate 31. The thin film 33 was a metal oxide film serving as a thermistor thin film. For the dry etching apparatus 10, an ion-beam etching apparatus not including the shielding part 13 was used as a comparative example and an ion-beam etching apparatus including the shielding part 13 was used as an example. The shielding part 13 in the example is provided at a position remote from the sample stage 11 so as to block part of the emitted etching medium 20 from reaching the sample 30.

The etching rates [nm/sec] in the comparative examples and the example were obtained at the upper end, center, and lower end of the thin film 33 as shown in the graph of FIG. 14. Table 1 shows the difference in etching rate between the peripheral portion (upper end and lower end) and the central portion of the thin film 33 in the comparative example and the example.

TABLE 1

| | Etching rate difference |
|---|---|
| Comparative example | About 0.01 nm |
| (without shielding part) | |
| Example | About 0.05 nm |
| (with shielding part) | |

From the results shown in the graph of FIG. 14 and Table 1, it was confirmed that the shielding part 13 increased the difference in etching rate between the peripheral portion and the central portion of the thin film 33.

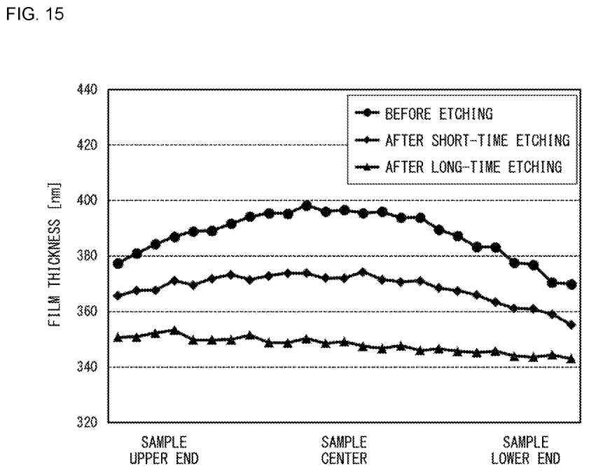

In the example using the shielding part 13, in three steps before etching, after short-time etching of 165 seconds, and after long-time etching of 330 seconds, the thickness [nm] of the thin film 33 was measured from the upper end to the lower end of the thin film 33 as shown in the graph of FIG. 15. Table 2 shows the in-plane film thickness distribution [%] in the three steps. The in-plane film thickness distribution (%) was calculated by the following equation:

$$D = ( {T}_{1} - {T}_{2} ) / ( {T}_{1} + {T}_{2} ) \times 100$$

D: In-plane film thickness distribution [%]
T₁: Thickness at the point having the largest thickness among measurement points [nm]
T₂: Thickness at the point having the smallest thickness among the measurement points [nm]

TABLE 2

| | In-plane film thickness |
|---|---|
| | distribution |
| Before etching | 3.77% |
| After short-time etching | 2.93% |
| After long-time etching | 1.54% |

From the results shown in the graph of FIG. 15 and Table 2, it was confirmed that the thickness of the thin film 33, which increases in thickness from the peripheral portion to the central portion, can be made nearly uniform in the plane by using the dry etching apparatus 10 of the example embodiment.

1. A dry etching apparatus comprising:
a rotatable sample stage on which a sample is mounted;
an etching source that irradiates the sample with an etching medium; and
a shielding part that is provided at a position remote from the sample stage so as to block part of the emitted etching medium from reaching the sample.

2. The dry etching apparatus according to claim 1, wherein at least one of the installation or non-installation of the shielding part, a position of the shielding part, a shape of the shielding part, and an irradiation angle of the etching medium on the sample is changeable.

3. The dry etching apparatus according to claim 1, further comprising a control unit that controls at least one of the etching source, the sample stage, and the shielding part to adjust a range of a blocking region where the etching medium is blocked by the shielding part.

4. The dry etching apparatus according to claim 3, wherein the control unit adjusts the range of the blocking region on the basis of an etching target that is a target of a degree of etching on each portion of the sample.

5. The dry etching apparatus according to claim 4, wherein the control unit sets the etching target on the basis of a state of the sample before etching and a state of the sample after target etching is performed.

6. The dry etching apparatus according to claim 1, wherein the etching source emits the etching medium to an overall surface of the sample mounted on the sample stage when the shielding part does not block the etching medium.
